(19) United States
(12) Patent Application Publication
(10) Pub. No.: US 2019/0280059 A1
(43) Pub. Date: Sep. 12, 2019

(54) OLED DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Jia TANG, Shenzhen (CN); Xiaoxing ZHANG, Shenzhen (CN); Jangsoon IM, Shenzhen (CN)

(21) Appl. No.: 16/045,156

(22) Filed: Jul. 25, 2018

Related U.S. Application Data
(63) Continuation of application No. PCT/CN2018/087314, filed on May 17, 2018.

(30) Foreign Application Priority Data
Mar. 7, 2018 (CN) 201810186722.9

(51) Int. Cl. H01L 27/32; H01L 51/56

(52) U.S. Cl. CPC H01L 27/3246; H01L 51/56; H01L 27/3276

(57) ABSTRACT

The invention provides an OLED display panel and manufacturing method, wherein the method comprises: providing a TFT substrate; forming a pixel definition layer comprising a plurality of island structures on the TFT backplane; wherein the island structure comprising a first conductor and a first insulator located at a periphery of the first conductor; providing a plurality of second conductors having a pointed or angular structure on the first conductor; forming an electronic layer on the pixel definition layer; the electronic layer comprising an electron transport layer and an electron injection layer; forming a cathode layer on the electron injection layer; applying an external field to the pixel definition layer, the second conductors breaking down the electron layer so the second conductors being electrically connected to the cathode layer, the external field comprising a current or electric field. The invention solves the IR drop problem in large-sized OLED display panel.

### CROSS REFERENCE TO RELATED APPLICATIONS

This application is a continuing application of PCT Patent Application No. PCT/CN2018/087314, entitled “OLED DISPLAY PANEL AND MANUFACTURING METHOD THEREOF”, filed on May 17, 2018, which claims priority to Chinese Patent Application No. CN201810186722.9, filed on Mar. 7, 2018, both of which are hereby incorporated in its entireties by reference.

### BACKGROUND OF THE INVENTION

### 1. Field of the Invention

The present invention relates to the field of display and, in particular, to the field of an organic light-emitting diode (OLED) display panel and manufacturing method thereof.

### 2. The Related Arts

When a large-sized organic light-emitting diode (OLED) display panel (i.e., an OLED display panel wherein an organic material is vapor-deposited on the entire surface, generally an OLED display panel produced on a 5th-generation line or higher) operates, an IR drop problem between the display center of the panel and the peripheral areas outside the display center exists (i.e., when the power supply voltage of the display panel is transmitted to the pixel circuit of the effective display area of the display panel through the wire, the power supply voltage will cause a direct current (DC) drop, i.e., IR drop, in the process of transmission because of the resistance in the wire, the IR drop will cause the uneven brightness in the display panel0, therefore, an additional auxiliary electrode must be provided on the backplane to provide additional assistance for areas with large voltage drop to make stable display of entire screen when the display panel operates. The IR drop in the small-sized OLED display panel is not obvious, and no auxiliary electrode is needed. At present, the main solution of the auxiliary electrode is to fabricate an inverted trapezoidal insulating pillar on the pixel definition layer. The fabrication cost of the inverted trapezoidal insulating pillar is high and the process is complex, which makes the backplane of EL/IJP-OLED (an OLED display panel prepared by vapor deposition and ink-jet printed) process harder for realization. Moreover, the inverted trapezoidal insulating column also occupies extra space. In addition, a contact hole must be included on the pixel definition layer to implement bonding of cathode and anode. These are disadvantageous to the design of the circuit and the design of the high pixel density (PPI) backplane.

### SUMMARY OF THE INVENTION

The primary object of the present invention is to provide an OLED display panel and manufacturing method thereof, able to reduce the wiring space of the thin film transistor (TFT) backplane, as well as solve the IR voltage drop problem in the large-size OLED display panel, and favorable to the design of the circuit design and the high PPI TFT backplane.

To solve the above technical issue, the present invention provides a manufacturing method of OLED display panel, which comprises the steps of:

providing a thin film transistor (TFT) substrate;

forming a pixel definition layer comprising a plurality of island structures on the TFT backplane; wherein the island structure comprising a first conductor and a first insulator located at a periphery of the first conductor;

providing a plurality of second conductors having a pointed or angular structure on the first conductor;

forming an electronic layer on the pixel definition layer; the electronic layer comprising an electron transport layer and an electron injection layer;

forming a cathode layer on the electron injection layer;

applying an external field to the pixel definition layer, the second conductors breaking down the electron layer so that the second conductors being electrically connected to the cathode layer, the external field comprising a current or an electric field.

Preferably, the manufacturing method further comprises:

forming a hole layer, a light-emitting layer, and the electron layer successively between adjacent island structures on the TFT backplane; the hole layer comprising a hole injection layer and a hole transport layer.

Preferably, the step of forming the light-emitting layer specifically comprises:

forming the light-emitting layer of OLED material on the hole transport layer by vapor deposition or ink-jet printing.

Preferably, the step of forming a pixel definition layer comprising a plurality of island structures on the TFT backplane comprises the following steps:

forming a second insulator of island shape on the TFT backplane;

etching the second insulator to form a first via;

forming a conductive material layer inside the first via; patterning the conductive material layer to obtain the first conductor.

Preferably, the step of providing a TFT backplane comprises the following steps:

forming a plurality of mutually independent light-shielding layers on a glass substrate;

forming a buffer layer on the glass substrate, and the buffer layer covering the light-shielding layer;

forming a semiconductor channel layer, a gate insulating layer, and a gate on the buffer layer and located above the light-shielding layer;

forming an interlayer spacer layer on the buffer layer, and the interlayer spacer layer covering the gate, the gate insulating layer, and the semiconductor channel layer;

etching the interlayer spacer layer to form at least a pair of second vias, and the at least one pair of second vias being located on both sides of the gate and above the semiconductor channel layer;

forming a source and a drain on the interlayer spacer layer, and the source and the drain being connected to the semiconductor channel layer through the at least one pair of second vias.

Preferably, the semiconductor channel layer is attached on the buffer layer or the gate is attached on the buffer layer, and the gate insulating layer is located between the gate and the semiconductor channel layer;

the semiconductor channel layer is made of a low-temperature poly silicon or a semiconductor oxide.

Preferably, the step of providing a TFT backplane further comprises the following steps:

forming a passivation layer on the interlayer spacer layer and forming a planarization layer on the passivation layer;

etching the planarization layer and the passivation layer to form at least a third via, and the at least one third via being located above the source or the drain;

forming at least an anode on the planarization layer, and the at least one anode being connected to the source or the drain through the third via.

The present invention also provides a manufacturing method of ©LED display panel, which comprises the steps of:

providing a thin film transistor (TFT) substrate;

forming a pixel definition layer comprising a plurality of island structures on the TFT backplane; wherein the island structure comprising a first conductor and a first insulator located at a periphery of the first conductor;

providing a plurality of second conductors having a pointed or angular structure on the first conductor;

forming an electronic layer on the pixel definition layer; the electronic layer comprising an electron transport layer and an electron injection layer;

forming a cathode layer on the electron injection layer;

applying an external field to the pixel definition layer, the second conductors breaking down the electron layer so that the second conductors being electrically connected to the cathode layer, the external field comprising a current or an electric field;

further comprising:

forming a hole layer, a light-emitting layer, and the electron layer successively between adjacent island structures on the TFT backplane; the hole layer comprising a hole injection layer and a hole transport layer;

the step of forming a pixel definition layer comprising a plurality of island structures on the TFT backplane comprising the following steps:

forming a second insulator of island shape on the TFT backplane;

etching the second insulator to form a first via;

forming a conductive material layer inside the first via, patterning the conductive material layer to obtain the first conductor.

Preferably, the step of forming the light-emitting layer specifically comprises:

forming the light-emitting layer of OLEO material on the hole transport layer by vapor deposition or ink-jet printing.

Preferably, the step of providing a TFT backplane comprises the following steps:

forming a plurality of mutually independent light-shielding layers on a glass substrate;

forming a buffer layer on the glass substrate, and the buffer layer covering the light-shielding layer;

forming a semiconductor channel layer, a gate insulating layer, and a gate on the buffer layer and located above the light-shielding layer;

forming an interlayer spacer layer on the buffer layer, and the interlayer spacer layer covering the gate, the gate insulating layer, and the semiconductor channel layer;

etching the interlayer spacer layer to form at least a pair of second vias, and the at least one pair of second vias being located on both sides of the gate and above the semiconductor channel layer;

forming a source and a drain on the interlayer spacer layer, and the source and the drain being connected to the semiconductor channel layer through the at least one pair of second vias.

Preferably, the semiconductor channel layer is attached on the buffer layer or the gate is attached on the buffer layer, and the gate insulating layer is located between the gate and the semiconductor channel layer;

the semiconductor channel layer is made of a low temperature poly silicon or a semiconductor oxide.

Preferably, the step of providing a TFT backplane further comprises the following steps:

forming a passivation layer on the interlayer spacer layer and forming a planarization layer on the passivation layer;

etching the planarization layer and the passivation layer to form at least a third via, and the at least one third via being located above the source or the drain;

forming at least an anode on the planarization layer, and the at least one anode being connected to the source or the drain through the third via.

The present invention also provides an OLEO display panel, which comprises: a thin film transistor (TFT) backplane, a pixel definition layer formed on the TFT backplane, an electron layer formed on the pixel definition layer, and a cathode layer formed on the electron layer;

wherein the electron layer comprising an electron transport layer and an electron injection layer; the pixel definition layer comprising a plurality of island structures, the island structure comprising a first conductor and a first insulator located at peripheral of the first conductor; the first conductor being disposed with a plurality of second conductors having a pointed or angular structure, and the second conductor being electrically connected to the cathode layer through the electron layer.

Preferably, The TFT backplane comprises a glass substrate, a plurality of mutually independent light-shielding layers formed on the glass substrate, a buffer layer formed on the glass substrate; a semiconductor channel layer, a gate insulating layer, and a gate formed on the buffer layer and located at a location above the light-shielding layers, and an interlayer spacer layer formed on the buffer layer;

wherein, the buffer layer covers the light-shielding layers, and the interlayer spacer layer covers the gate, the gate insulating layer, and the semiconductor channel layer;

the interlayer spacer layer is disposed with at least a pair of second vias, and the at least one pair of second vias are located on both sides of the gate and above the semiconductor channel layer;

the interlayer spacer layer is disposed with a source and a drain, and the source and the drain are connected to the semiconductor channel layer through the at least one pair of second vias.

Preferably, the OLEO display panel further comprises: a hole layer and a light-emitting layer between adjacent island structures on the TFT backplane; the electron layer covering the light-emitting layer, and the hole layer comprising a hole injection layer and a hole transport layer;

the TFT backplane further comprises: a passivation layer on the interlayer spacer layer and a planarization layer on the passivation layer;

the planarization layer and the passivation layer being disposed with at least a third via, and the at least one third via being located above the source or the drain;

the planarization layer being disposed with at least an anode, and the at least one anode being connected to the source or the drain through the third via.

The embodiments of the present invention provide the following advantages: a middle portion of the pixel definition layer is configured as a first conductor and the peripheral is configured as a non-conductive first insulator; a layer of interconnected with pointed or angularly-shaped tip of island-shaped second conductors is formed on the surface of the first conductor. In a large-sized OLED display panel, the electron layer is thin and easily damaged by an external field (current, electric field, etc.). When an external field is applied to the area, the second conductors cause damage to the electron layer at the top position, either burnout or burn-in, in which case the first conductor is directly connected to the cathode layer, and the external field provides a cathode assistance through the conductive first conductor.

The pixel definition layer of the present invention can be used as an auxiliary electrode to solve the IR drop problem when the display panel is lit, and the present invention does not provide a separate inverted trapezoidal auxiliary electrode in addition to the pixel definition layer, thereby reducing the cost of the display panel and the manufacture difficulty. Moreover, the invention does not need to provide a connection hole for realizing the bonding of the cathode and the anode in the pixel definition layer. Therefore, the present invention reduces the wiring space of the TFT backplane, solves the IR drop problem of the large-size OLED display panel and is advantageous to the design of the circuit and the high PPI TFT backplane.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort.

FIG. 1 is a schematic view showing the structure of a TFT backplane provided by the present invention.

FIG. 2 is a schematic view showing the OLED display panel before applying external field to the pixel definition layer provided by the present invention.

FIG. 3 is a schematic view showing the electron layer provided by the present invention.

FIG. 4 is a schematic view showing the OLED display panel after applying external field to the pixel definition layer provided by the present invention.

FIG. 5 is a schematic view showing the hole layer provided by the present invention.

FIG. 6 is a schematic view showing the formation of second insulator on the structure of a TFT backplane provided by the present invention.

FIG. 7 is a schematic view showing the etching to form the first via on the second insulator provided by the present invention.

FIG. 8 is a schematic view showing the etching to form the second via on the interlayer spacer layer provided by the present invention.

FIG. 9 is a schematic view showing the etching to form the third via on the passivation layer and the planarization layer provided by the present invention.

### DETAILED DESCRIPTION OF THE PREFERRED EMBODIMENTS

To further explain the technical means and effect of the present invention, the following refers to embodiments and drawings for detailed description. Apparently, the described embodiments are merely some embodiments of the present invention, instead of all embodiments. All other embodiments based on embodiments in the present invention and obtained by those skilled in the art without departing from the creative work of the present invention are within the scope of the present invention.

The terms “comprising” and “having” and any variations thereof appearing in the specification, claims, and drawings of the present application are intended to cover non-exclusive inclusion. For example, a process, method, system, product, or device that includes a series of steps or units is not limited to the listed steps or units, but optionally also includes steps or units not listed, or alternatively, other steps or units inherent to these processes, methods, products or equipment. In addition, the terms “first”, “second” and “third” are used to distinguish different objects and not intended to describe a particular order.

The present invention provides a manufacturing method of OLEO display panel, which comprises the steps of:

providing a thin film transistor (TFT) substrate 1 as shown in FIG. 1;

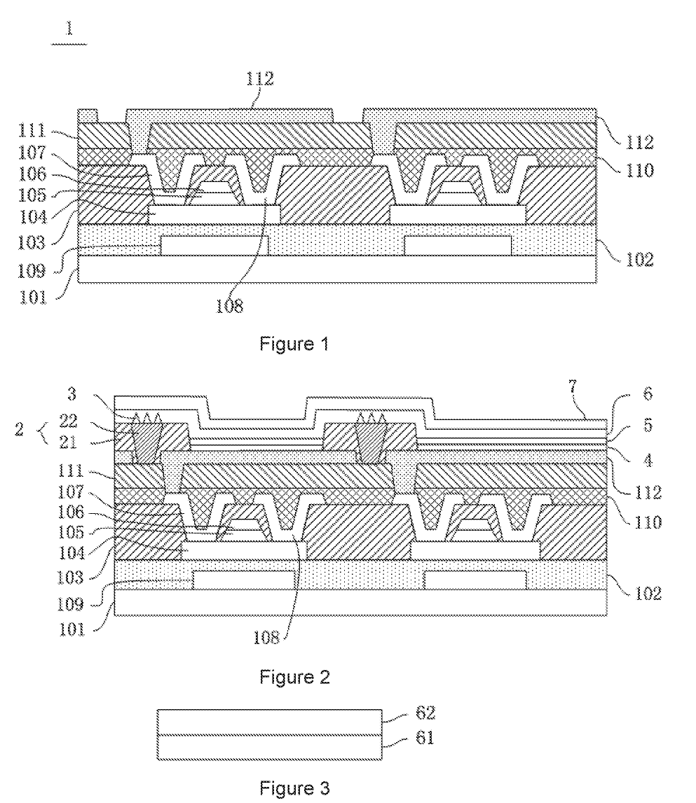

as shown in FIG. 2, forming a pixel definition layer comprising a plurality of island structures 2 on the TFT backplane 1; wherein the island structure 2 comprising a first conductor 22 and a first insulator 21 located at a periphery of the first conductor 22;

providing a plurality of second conductors 3 having a pointed or angular structure on the first conductor 22;

forming an electronic layer 6 on the pixel definition layer; as shown in FIG. 3, the electronic layer 6 comprising an electron transport layer 61 and an electron injection layer 62; the electron transport layer 61 being located between the electron injection layer 62 and the pixel definition layer; the electron layer 6 being relatively thin and having a thickness not exceeding 50 nm;

forming a cathode layer 7 on the electron injection layer 62;

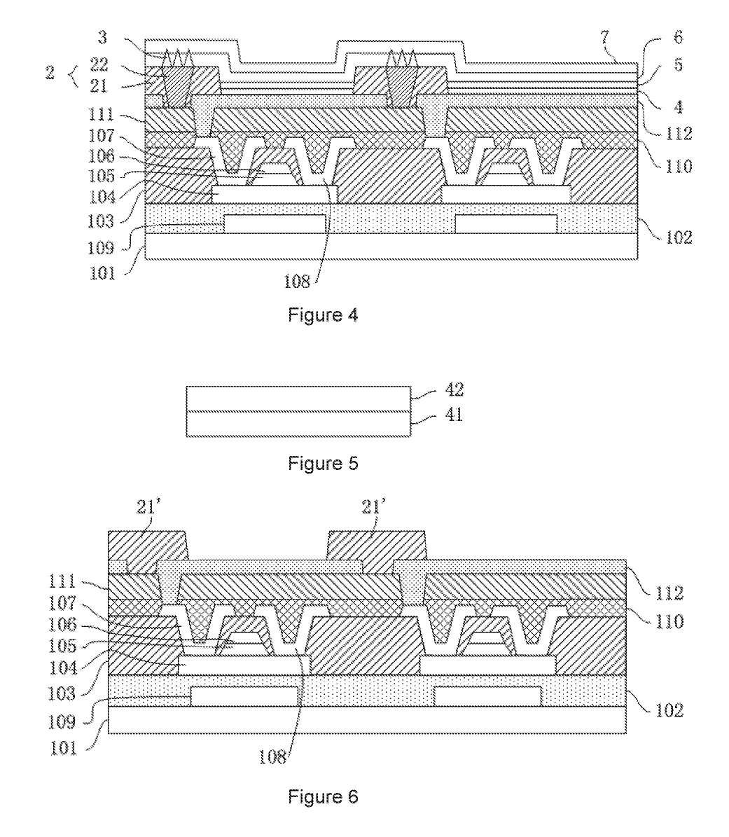

applying an external field to the pixel definition layer, as shown in FIG. 4, the second conductors 3 breaking down the electron layer 6 so that the second conductors 3 being electrically connected to the cathode layer 7, the external field providing assistance to the cathode layer 7 through the pixel definition layer to solve the IR drop problem, the external field comprising a current or an electric field.

Furthermore, the manufacturing method of OLE© display panel further comprises:

forming a hole layer 4, a light-emitting layer 5, and the electron layer 6 successively between adjacent island structures 2 on the TFT backplane 1; as shown in FIG. 5, the hole layer 4 comprises a hole injection layer 41 and a hole transport layer 42. The hole transport layer 42 is located between the hole injection layer 41 and the light-emitting layer 5.

Furthermore, the step of forming the light-emitting layer specifically comprises:

forming the light-emitting layer 5 of OLEO material on the hole transport layer 42 by vapor deposition or ink-jet printing. Preferably, when forming the light-emitting layer 5 of OLEO material on the hole transport layer 42 by vapor deposition, the first insulator 21 is made of a non-hydrophobic material; when forming the light-emitting layer 5 of OLEO material on the hole transport layer 42 by ink-jet printing, the first insulator 21 is made of a hydrophobic material.

The hole injection layer 41, the hole transport layer 42 and the light-emitting layer 5 can all be prepared by vapor deposition or ink-jet printing.

Preferably, the step of forming a pixel definition layer comprising a plurality of island structures 2 on the TFT backplane 1 comprises the following steps:

as shown in FIG. 6, forming a second insulator 21′ of island shape on the TFT backplane 1;

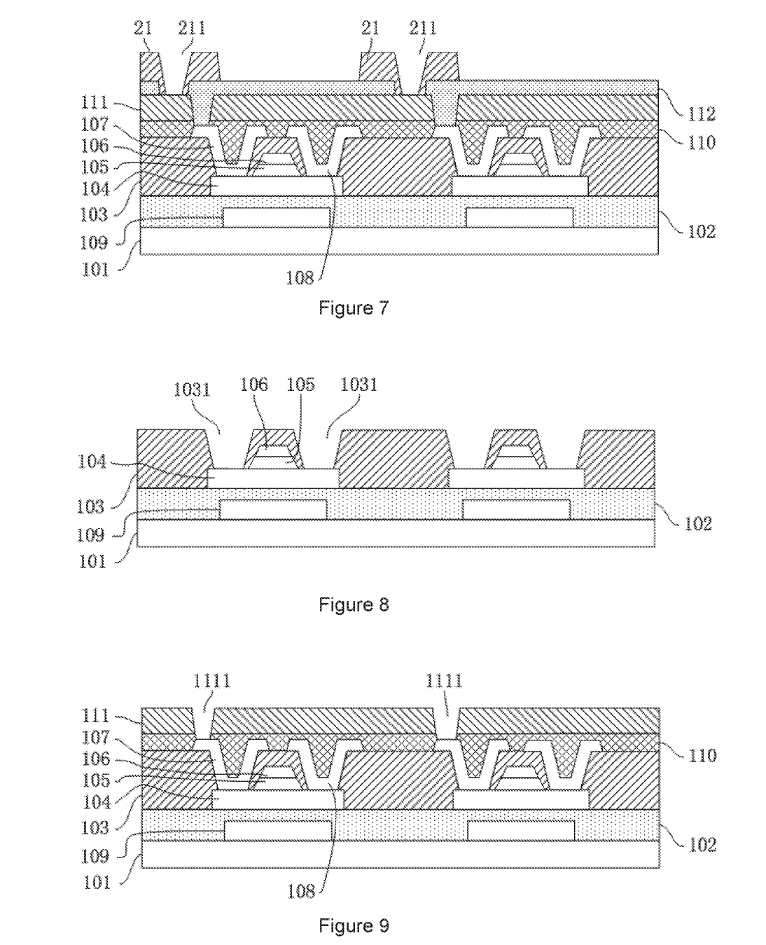

as shown in FIG. 7, etching the second insulator 21′ to form a first via 211;

forming a conductive material layer inside the first via 211 by coating an organic conductive material or depositing an inorganic conductive material or by physical vapor deposition/chemical vapor deposition to deposit an inorganic conductive material, patterning the conductive material layer to obtain the first conductor 22. Preferably, the first conductor 22 and the second conductor 3 may be made of the same conductive material or different conductive materials. The shape of the first conductor 22 may be one of the following shapes: a square shape, a cylindrical shape, a triangular shape, or a combination of the above.

Furthermore, the step of providing a TFT backplane 1 comprises the following steps:

forming a plurality of mutually independent light-shielding layers 109 on a glass substrate 101;

forming a buffer layer 102 on the glass substrate 101, and the buffer layer 102 covering the light-shielding layer 109;

forming a semiconductor channel layer 104, a gate insulating layer 105; and a gate 106 on the buffer layer 102 and located above the light-shielding layer 109;

forming an interlayer spacer layer 103 on the buffer layer 102, and the interlayer spacer layer 103 covering the gate 106, the gate insulating layer 105, and the semiconductor channel layer 104;

as shown in FIG. 8, etching the interlayer spacer layer 103 to form at least a pair of second vias 1031, and the at least one pair of second vias 1031 being located on both sides of the gate 106 and above the semiconductor channel layer 104;

forming a source 107 and a drain 108 on the interlayer spacer layer 103, and the source 107 and the drain 108 being connected to the semiconductor channel layer 104 through the at least one pair of second vias 1031.

Moreover, the semiconductor channel layer 104 is attached on the buffer layer 102 or the gate 106 is attached on the buffer layer 102, and the gate insulating layer 105 is located between the gate 106 and the semiconductor channel layer 104; the semiconductor channel layer 104 is made of a low-temperature poly silicon or a semiconductor oxide, or even a semiconductor material manufactured by a solid-phase crystallization method. When the semiconductor channel layer 104 is attached to the buffer layer 102, the TFT backplane 1 is of a top-gate structure. When the gate 106 is attached to the buffer layer 102, the TFT backplane 1 is of a bottom-gate structure.

Furthermore, the step of providing a TFT backplane 1 further comprises the following steps:

forming a passivation layer 110 on the interlayer spacer layer 102 and forming a planarization layer 111 on the passivation layer 110;

as shown in FIG. 9, etching the planarization layer 111 and the passivation layer 110 to form at least a third via 1111, and the at least one third via 1111 being located above the source 107; in other embodiments, the first via 1111 may be located above the drain 108;

forming at least an anode 112 on the planarization layer 111, and the at least one anode 112 being connected to the source 107 through the third via 1111. In other embodiments, the at least one anode 112 is connected to the drain 108 through the third via 1111. The aforementioned first conductor 22 is insulated from the anode 112 on the TFT backplane 1 by the first insulator 21.

The present invention also provides an OLED display panel, which comprises: a thin film transistor (TFT) backplane 1, a pixel definition layer formed on the TFT backplane 1, an electron layer 6 formed on the pixel definition layer, and a cathode layer 7 formed on the electron layer 6.

Wherein, the electron layer 6 comprises an electron transport layer 61 and an electron injection layer 62; the pixel definition layer comprises a plurality of island structures 2, the island structure 2 comprises a first conductor 22 and a first insulator 21 located at peripheral of the first conductor 22;

the first conductor 22 is disposed with a plurality of second conductors 3 having a pointed or angular structure, and the second conductor 3 is electrically connected to the cathode layer 7 through the electron layer 6.

Furthermore, The TFT backplane 1 comprises: a glass substrate 101, a plurality of mutually independent light-shielding layers 109 formed on the glass substrate 101, a buffer layer 102 formed on the glass substrate 101, a semiconductor channel layer 104, a gate insulating layer 105, and a gate 106 formed on the buffer layer 102 and located at a location above the light-shielding layers 109, and an interlayer spacer layer 103 formed on the buffer layer 102.

Wherein, the buffer layer 102 covers the light-shielding layers 109, and the interlayer spacer layer 103 covers the gate 106, the gate insulating layer 105, and the semiconductor channel layer 104;

the interlayer spacer layer 103 is disposed with at least a pair of second vias 1031, and the at least one pair of second vias 1031 are located on both sides of the gate 106 and above the semiconductor channel layer 104;

the interlayer spacer layer 103 is disposed with a source 107 and a drain 108, and the source 107 and the drain 108 are connected to the semiconductor channel layer 104 through the at least one pair of second vias 1031.

Furthermore, the OLED display panel further comprises: a hole layer 4 and a light-emitting layer 5 between adjacent island structures 2 on the TFT backplane 1; the electron layer 4 covering the light-emitting layer 5, and the hole layer 4 comprising a hole injection layer 41 and a hole transport layer 42.

The TFT backplane 1 further comprises: a passivation layer 110 on the interlayer spacer layer 103 and a planarization layer 111 on the passivation layer 110.

The planarization layer 111 and the passivation layer 110 are disposed with at least a third via 1111, and the at least one third via 1111 is located above the source 107 or the drain 108.

The planarization layer 111 is disposed with at least an anode 112, and the at least one anode 112 is connected to the source 107 or the drain 108 through the third via 1111.

In summary, in the OLED display panel and manufacturing method thereof provided by the present invention, in the preparation of a large-sized display panel, such as, active-matrix organic light-emitting diode (AMOLED) display panel, a middle portion of the pixel definition layer is configured as a first conductor 22 and the peripheral is configured as a non-conductive first insulator 21; a layer of interconnected with pointed or angularly-shaped tip of island-shaped second conductors 3 is formed on the surface of the first conductor 22. In a large-sized OLED display panel, the electron layer 6 is thin and easily damaged by an external field (current, electric field, etc.). When an external field is applied to the area, the second conductors 3 cause damage to the electron layer 6 at the top position, either burnout or burn-in, in which case the first conductor 22 is directly connected to the cathode layer 7, and the external field provides a cathode assistance through the conductive first conductor 22.

The first conductor 22 of the pixel definition layer of the present invention can be used as an auxiliary electrode to solve the IR drop problem when the display panel is lit, and the present invention does not provide a separate inverted trapezoidal auxiliary electrode in addition to the pixel definition layer, thereby reducing the cost of the display panel and the manufacture difficulty. Moreover, the invention does not need to provide a connection hole for realizing the bonding of the cathode and the anode 112 in the pixel definition layer. Therefore, the present invention reduces the wiring space of the TFT backplane 1, solves the IR drop problem of the large-size OLED display panel and is advantageous to the design of the circuit and the high PPI TFT backplane 1.

It should be noted that each of the embodiments in this specification is described in a progressive manner, each of which is primarily described in connection with other embodiments with emphasis on the difference parts, and the same or similar parts may be seen from each other. For the device embodiment, since it is substantially similar to the method embodiment, the description is relatively simple and the relevant description may be described in part of the method embodiment.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claim of the present invention.

What is claimed is:

1. A manufacturing method of organic light-emitting diode (OLEO) display panel, comprising:
providing a thin film transistor (TFT) substrate;
forming a pixel definition layer comprising a plurality of island structures on the TFT backplane; wherein the island structure comprising a first conductor and a first insulator located at a periphery of the first conductor;
providing a plurality of second conductors having a pointed or angular structure on the first conductor;
forming an electronic layer on the pixel definition layer; the electronic layer comprising an electron transport layer and an electron injection layer;
forming a cathode layer on the electron injection layer;
applying an external field to the pixel definition layer, the second conductors breaking down the electron layer so that the second conductors being electrically connected to the cathode layer, the external field comprising a current or an electric field.

2. The manufacturing method of OLED display panel as claimed in claim 1, further comprising the following step:
forming a hole layer, a light-emitting layer, and the electron layer successively between adjacent island structures on the TFT backplane; the hole layer comprising a hole injection layer and a hole transport layer.

3. The manufacturing method of OLED display panel as claimed in claim 2, wherein the step of forming the light-emitting layer specifically comprises:
forming the light-emitting layer of OLED material on the hole transport layer by vapor deposition or ink-jet printing.

4. The manufacturing method of OLED display panel as claimed in claim 1, wherein the step of forming a pixel definition layer comprising a plurality of island structures on the TFT backplane comprises the following steps:
forming a second insulator of island shape on the TFT backplane;
etching the second insulator to form a first via;
forming a conductive material layer inside the first via, patterning the conductive material layer to obtain the first conductor.

5. The manufacturing method of OLED display panel as claimed in claim 1, wherein the step of providing a TFT backplane comprises the following steps:
forming a plurality of mutually independent light-shielding layers on a glass substrate;
forming a buffer layer on the glass substrate, and the buffer layer covering the light-shielding layer;
forming a semiconductor channel layer, a gate insulating layer, and a gate on the buffer layer and located above the light-shielding layer;
forming an interlayer spacer layer on the buffer layer, and the interlayer spacer layer covering the gate, the gate insulating layer, and the semiconductor channel layer;
etching the interlayer spacer layer to form at least a pair of second vias, and the at least one pair of second vias being located on both sides of the gate and above the semiconductor channel layer;
forming a source and a drain on the interlayer spacer layer, and the source and the drain being connected to the semiconductor channel layer through the at least one pair of second vias.

6. The manufacturing method of OLED display panel as claimed in claim 5, wherein the semiconductor channel layer is attached on the buffer layer or the gate is attached on the buffer layer, and the gate insulating layer is located between the gate and the semiconductor channel layer;
the semiconductor channel layer is made of a low-temperature poly silicon or a semiconductor oxide.

7. The manufacturing method of OLED display panel as claimed in claim 5, wherein the step of providing a TFT backplane further comprises the following steps:
forming a passivation layer on the interlayer spacer layer and forming a planarization layer on the passivation layer;
etching the planarization layer and the passivation layer to form at least a third via, and the at least one third via being located above the source or the drain;
forming at least an anode on the planarization layer, and the at least one anode being connected to the source or the drain through the third via.

8. A manufacturing method of organic light-emitting diode (OLED) display panel, comprising:
providing a thin film transistor (TFT) substrate;
forming a pixel definition layer comprising a plurality of island structures on the TFT backplane; wherein the island structure comprising a first conductor and a first insulator located at a periphery of the first conductor;
providing a plurality of second conductors having a pointed or angular structure on the first conductor;
forming an electronic layer on the pixel definition layer; the electronic layer comprising an electron transport layer and an electron injection layer;
forming a cathode layer on the electron injection layer;
applying an external field to the pixel definition layer, the second conductors breaking down the electron layer so that the second conductors being electrically connected to the cathode layer, the external field comprising a current or an electric field;
further comprising the following step:
forming a hole layer, a light-emitting layer, and the electron layer successively between adjacent island structures on the TFT backplane; the hole layer comprising a hole injection layer and a hole transport layer;
wherein the step of forming a pixel definition layer comprising a plurality of island structures on the TFT backplane comprising the following steps:
forming a second insulator of island shape on the TFT backplane;
etching the second insulator to form a first via;
forming a conductive material layer inside the first via, patterning the conductive material layer to obtain the first conductor.

9. The manufacturing method of OLED display panel as claimed in claim 8, wherein the step of forming the light-emitting layer specifically comprises:
forming the light-emitting layer of OLED material on the hole transport layer by vapor deposition or ink-jet printing.

10. The manufacturing method of OLED display panel as claimed in claim 8, wherein the step of providing a TFT backplane comprises the following steps:
forming a plurality of mutually independent light-shielding layers on a glass substrate;
forming a buffer layer on the glass substrate, and the buffer layer covering the light-shielding layer;
forming a semiconductor channel layer, a gate insulating layer, and a gate on the buffer layer and located above the light-shielding layer;
forming an interlayer spacer layer on the buffer layer, and the interlayer spacer layer covering the gate, the gate insulating layer, and the semiconductor channel layer;
etching the interlayer spacer layer to form at least a pair of second vias, and the at least one pair of second vias being located on both sides of the gate and above the semiconductor channel layer;
forming a source and a drain on the interlayer spacer layer, and the source and the drain being connected to the semiconductor channel layer through the at least one pair of second vias.

11. The manufacturing method of OLED display panel as claimed in claim 10, wherein the semiconductor channel layer is attached on the buffer layer or the gate is attached on the buffer layer, and the gate insulating layer is located between the gate and the semiconductor channel layer;
the semiconductor channel layer is made of a low-temperature poly silicon or a semiconductor oxide.

12. The manufacturing method of OLED display panel as claimed in claim 10, wherein the step of providing a TFT backplane further comprises the following steps:
forming a passivation layer on the interlayer spacer layer and forming a planarization layer on the passivation layer;
etching the planarization layer and the passivation layer to form at least a third via, and the at least one third via being located above the source or the drain;
forming at least an anode on the planarization layer, and the at least one anode being connected to the source or the drain through the third via.

13. An organic light-emitting diode (OLED) display panel, comprising: a thin film transistor (TFT) backplane, a pixel definition layer formed on the TFT backplane, an electron layer formed on the pixel definition layer, and a cathode layer formed on the electron layer;
wherein the electron layer comprising an electron transport layer and an electron injection layer; the pixel definition layer comprising a plurality of island structures, the island structure comprising a first conductor and a first insulator located at peripheral of the first conductor;
the first conductor being disposed with a plurality of second conductors having a pointed or angular structure, and the second conductor being electrically connected to the cathode layer through the electron layer.

14. The OLED display panel as claimed in claim 13, wherein the buffer layer covers the light-shielding layers, and the interlayer spacer layer covers the gate, the gate insulating layer, and the semiconductor channel layer;
the interlayer spacer layer is disposed with at least a pair of second vias, and the at least one pair of second vias are located on both sides of the gate and above the semiconductor channel layer;
the interlayer spacer layer is disposed with a source and a drain, and the source and the drain are connected to the semiconductor channel layer through the at least one pair of second vias.

15. The OLED display panel as claimed in claim 4, wherein the OLED display panel further comprises:
a hole layer and a light-emitting layer between adjacent island structures on the TFT backplane; the electron layer covering the light-emitting layer; and the hole layer comprising a hole injection layer and a hole transport layer;
the TFT backplane further comprises: a passivation layer on the interlayer spacer layer and a planarization layer on the passivation layer;
the planarization layer and the passivation layer being disposed with at least a third via, and the at least one third via being located above the source or the drain;
the planarization layer being disposed with at least an anode; and the at least one anode being connected to the source or the drain through the third via.
